(19) United States
(12) Patent Application Publication
(10) Pub. No.: US 2026/0298564 A1
(43) Pub. Date: Oct. 1, 2026

(54) COOLING APPARATUS, SUBSTRATE PROCESSING APPARATUS AND A METHOD FOR COOLING A PROCESSING LIQUID

(71) Applicant: SCREEN Holdings Co., Ltd., Kyoto (JP)

(72) Inventors: Tomoaki AIHARA, Kyoto (JP); Tetsuya WATANABE, Kyoto (JP)

(21) Appl. No.: 19/572,305

(22) Filed: Mar. 19, 2026

(30) Foreign Application Priority Data
Mar. 25, 2025 (JP) 2025-049600

(51) Int. Cl. F28F 27/02; F28D 7/16

(52) U.S. Cl. CPC F28F 27/02; F28D 7/16

(57) ABSTRACT

A cooling apparatus according to the present invention includes a cooling medium output part for outputting the cooling medium, a heat exchanger for cooling the processing liquid by the cooling medium, a supply flow path for causing the cooling medium to circulate between the cooling medium output part and the heat exchanger, a bypass flow path for returning the cooling medium from the cooling medium output part to the cooling medium output part without passing through the heat exchanger, a temperature detector for detecting the temperature of the processing liquid output from the heat exchanger, and a controller for controlling the temperature of the processing liquid to be output from the heat exchanger by regulating a flow rate ratio of the cooling medium to flow in the cooling medium supply flow path and the bypass flow path on the basis of temperature detection result.

### CROSS REFERENCE TO RELATED APPLICATION

The disclosure of Japanese Patent Application No.2025-049600 filed on Mar. 25, 2025 including specification, drawings and claims is incorporated herein by reference in its entirety.

### BACKGROUND OF THE INVENTION

### 1. Field of the Invention

This invention relates to a technique of cooling and outputting a processing liquid to be used, for example, for processing a substrate.

### 2. Description of the Related Art

In a process of manufacturing various kinds of substrates such as semiconductor substrates or glass substrates, for example, processing liquids at various temperatures having various compositions are used for processing the substrates. In some cases, water prepared by cooling high-purity water such as de-ionized water or pure water to a temperature around its freezing point (0° C.) (resultant water is simply called “cool water” herein) is required to be used as these processing liquids. As an example, according to a technique shown in JP2024-134431A (Patent Literature 1) disclosed previously by the applicant of the present application, de-ionized water (DIW) temperature-regulated to a low temperature is used as a cooling medium and brought into contact with a back surface of a substrate for the purpose of cooling the substrate heated during a course of a process.

According to a cooling method adoptable as a method of generating such a processing liquid at a low temperature, a cooling medium and the processing liquid are input to a heat exchanger, and the processing liquid is cooled through heat exchange between the cooling medium and the processing liquid. As the cooling medium in this case, a cooling medium cooled by a device called a chiller may be used, for example. While such a chiller device is suitable for maintaining the temperature of the cooling medium at a constant temperature lower than room temperature, it does not have high capability to follow change in a set temperature. Specifically, it takes a comparatively long time until the temperature of the cooling medium is stabilized at a new target temperature. For this reason, if the cooling medium output from the chiller device is to be input to the heat exchanger and to be used for cooling the processing liquid, a longer time is required from when the temperature of the cooling medium is changed to when this change is reflected in the temperature of the processing liquid.

As described above, according to the method of changing the temperature of the cooling medium for the purpose of regulating the temperature of the processing liquid, it is difficult to regulate the temperature of the processing liquid finely due to the low responsiveness thereof. In particular, if a cooling target temperature of the processing liquid is a temperature approximate to a freezing point thereof, high controllability is required over the temperature of the processing liquid in order to prevent freezing of the processing liquid.

### SUMMARY OF THE INVENTION

This invention has been made in view of the above problem, and provides a cooling technique with excellent controllability that is applicable even to a case where a target temperature is approximate to a freezing point, for example.

One aspect of the present invention is intended for a cooling apparatus configured to cool and output a processing liquid, comprising: a cooling medium output part configured to output the cooling medium; a heat exchanger configured to cool the processing liquid through heat exchange with the cooling medium; a supply flow path former configured to form a cooling medium supply flow path for causing the cooling medium to circulate between the cooling medium output part and the heat exchanger; a bypass flow path former configured to form a bypass flow path for returning the cooling medium output from the cooling medium output part to the cooling medium output part without passing the cooling medium through the heat exchanger; a temperature detector configured to detect the temperature of the processing liquid output from the heat exchanger; and a controller configured to control the temperature of the processing liquid to be output from the heat exchanger by regulating a flow rate ratio of the cooling medium to flow in each of the cooling medium supply flow path and the bypass flow path on the basis of detection result from the temperature detector.

According to the invention thus configured, the cooling medium output from the cooling medium output part is distributed between the flow path passing through the heat exchanger and the bypass flow path not passing through the heat exchanger. The flow rate ratio therebetween is regulated using temperature detection result about the processing liquid. In this configuration, the cooling medium to contribute to cooling of the processing liquid is only the cooling medium to be input to the heat exchanger, out of the vooling medium to be output from the cooling medium output part. A larger quantity of the input cooling medium enhances the performance of cooling the processing liquid at the heat exchanger. In other words, the cooling performance at the heat exchanger changes in response to the flow rate of the cooling medium to be input thereto.

The present invention takes advantage of this to regulate the flow rate ratio of the cooling medium to be distributed on the basis of temperature detection result about the processing liquid, thereby controlling the temperature of the processing liquid. This eliminates the need to change the temperature of the cooling medium itself to settle the problem of resultant bad responsiveness. To be more strict, a certain degree of time delay remains from when the flow rate of the cooling medium is changed on the basis of temperature detection result about the processing liquid to when this changes is reflected in the temperature of the processing liquid. However, as the flow rate of the cooling medium itself is changed readily, this time delay is improved considerably compared to time delay caused by changing the temperature of the cooling medium.

On the other hand, the flow rate ratio of the cooling medium can be changed continuously, namely, steplessly in principle. This achieves high controllability in terms of the temperature of the processing liquid to be cooled and to be output. Specifically, it is possible to regulate the temperature of the processing liquid finely. Thus, even if a target temperature for cooling is approximate to a freezing point of the processing liquid, it is still possible to maintain a temperature stably without causing freezing of the processing liquid.

Another aspect of the present invention is intended for a substrate processing apparatus comprising: a cooling part having the same configuration as the above cooling apparatus; a substrate processor configured to process a substrate using the processing liquid output from the cooling part; and a supply pipe configured to supply the processing liquid from the cooling part to the substrate processor. According to the invention thus configured, it is possible to supply the processing liquid to the substrate processor at a required temperature and a stable temperature on the basis of principles same as those applied to the above cooling apparatus. Therefore, it is possible to process the substrate favorably at the substrate processor.

Another aspect of the present invention is intended for a cooling method configured to cool and output a processing liquid, comprising: branching a cooling medium supplied from a cooling medium supply source at a predetermined flow rate ratio into a flow path for inputting the cooling medium to a heat exchanger and a flow path bypassing the heat exchanger; cooling the processing liquid through heat exchange with the cooling medium at the heat exchanger; and detecting the temperature of the processing liquid output from the heat exchanger and regulating the flow rate ratio on the basis of result of the detection, thereby controlling the temperature of the processing liquid.

According to the invention thus configured, the cooling medium is distributed between the flow path passing through the heat exchanger and the flow path not passing through the heat exchanger, and the flow rate ratio therebetween is regulated in response to temperature detection result about the output processing liquid. Thus, on the basis of principles same as those applied to the invention relating to the cooling apparatus described above, it is possible to realize temperature regulation with excellent controllability and stability.

As described above, according to the present invention, the temperature of the processing liquid is controlled by regulating the flow rate of the cooling medium to be input to the heat exchanger instead of regulating the temperature of the cooling medium. The flow rate of the cooling medium is, in principle, changeable steplessly, so that the temperature of the processing liquid can be controlled finely with excellent controllability. Thus, even if a cooling target temperature is approximate to a freezing point of the processing liquid, it is still possible to prevent freezing of the processing liquid.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 shows a schematic configuration of a substrate processing system according to a first embodiment of the present invention;

FIG. 2 shows an exemplary configuration of the cooling unit;

FIGS. 3A to 3C show an exemplary configuration of the heat exchanger;

FIGS. 4A and 4B explain temperature regulating operation at the cooling unit;

FIG. 5 is a flowchart showing the substance of a temperature regulating process according to this embodiment; and

FIG. 6 shows a schematic configuration of a second embodiment of a substrate processing system including a cooling apparatus according to the present invention.

### DETAILED DESCRIPTION OF THE PREFERRED EMBODIMENTS

### First Embodiment

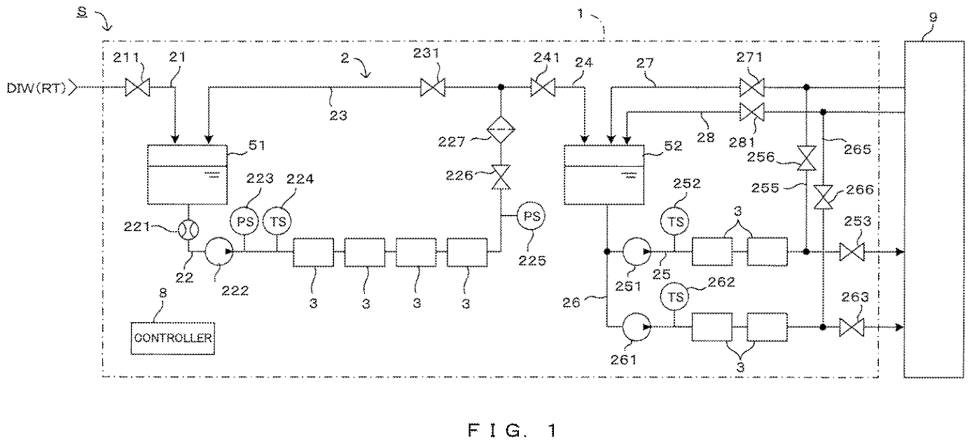

FIG. 1 shows a schematic configuration of a substrate processing system according to a first embodiment of the present invention. This substrate processing system S includes a processing liquid supplier 1 and a substrate processor 9. The processing liquid supplier 1 cools pure water or de-ionized water supplied from an external supply source to a predetermined temperature and outputs the cooled water as a processing liquid. The substrate processor 9 processes a processing target substrate using the processing liquid supplied from the processing liquid supplier 1. In the following, DIW will be described as a representative of the processing liquid. The substrate processor 9 may be configured to supply this processing liquid as it is to the substrate, or may be configured to mix the processing liquid with a different type of chemical or an organic solvent such as isopropyl alcohol (IPA) and supply a resultant liquid to the substrate, for example. While a semiconductor wafer is applicable as the substrate to be processed, for example, the substrate is not limited to this. While a representative process by the substrate processor 9 includes a rinsing process, wet cleaning, and wet etching performed by supplying a processing liquid, a chemical or the like to the substrate, it is not particularly limited.

The processing liquid supplier 1 includes a pipe system 2 for supplying the DIW to the substrate processor 9. Various types of functional units are provided appropriately along the piping to form a flow path of the processing liquid. More specifically, a control valve 211 is interposed in a pipe 21 connected to an external DIW supply source, and a terminal of the pipe 21 is connected to a primary reservoir tank 51. When the control valve 211 is opened in response to a control command from a controller 8 responsible for control over the behavior of the device as a whole, the DIW at room temperature (RT) supplied from the outside flows into the primary reservoir tank 51 through the pipe 21.

In the following, terms “flow direction,” “upstream side,” and “downstream side” are used for defining positions along a flow path of the processing liquid or a cooling medium. Unless specified otherwise, these terms show a flow direction of a liquid at a corresponding position along the flow path, and an upstream side and a downstream side of this flow direction.

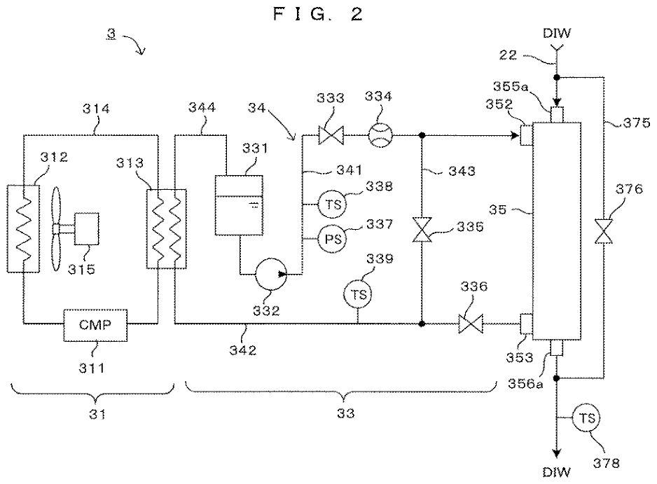

A pipe 22 is connected to a lower part of the primary reservoir tank 51. A flowmeter 221, a feed pump 222, a pressure sensor 223, a temperature sensor 224, a cooling unit 3, a pressure sensor 225, a control valve 226, a filter 227, and others are connected to the pipe 22. Each of these functional units may be added appropriately, as needed, to a position other than the illustrated position, or some of these functional units may be omitted. As an example, pressure reduction between the upstream side (primary side) and the downstream side (secondary side) with respect to a heat exchanger 35 (FIG. 2) disposed to the cooling unit 3 caused by pressure loss at the heat exchanger 35 can be acquired as data or can be calculated through experiment or simulation conducted previously. Thus, in one configuration, the pressure sensor 225 on the downstream side with respect to the heat exchanger 35 may be omitted.

Each of the flowmeter 221 and flowmeters described later detects the flow rate of a liquid in a flow path. Each of the feed pump 222 and feed pumps described later feeds a liquid supplied from the upstream side of the flow path toward the downstream side. Each of the pressure sensor 225 and pressure sensors described later detects the pressure of the liquid in the flow path. Each of the temperature sensor 224 and temperature sensors described later detects the temperature of the liquid in the flow path.

Each of the flowmeters, the feed pumps, the pressure sensors, and the temperature sensors is communicably connected to the controller 8. An output signal from each of the flowmeters, the pressure sensors, and the temperature sensors is transmitted to the controller 8. Each feed pumps and each control valves described later operate in response to a control command from the controller 8 to regulate the flow of the processing liquid in the flow path. The controller 8 controls the behaviors of movable parts including the feed pumps and the control valves in response to a control program prepared in advance and signals transmitted from sensors including the flowmeters, the pressure sensors, and the temperature sensors.

The cooling unit 3 has the function of reducing the temperature of an incoming liquid and outputting the resultant liquid. A final temperature of the processing liquid to be output from the cooling unit 3 is not particularly limited. Meanwhile, the final temperature may be set to a temperature lower than room temperature and slightly higher than 0° C. as a freezing point of the DIW, for example, and may be set to 5° C., for example. The number of the cooling units 3 may be one. Meanwhile, in order to reduce the temperature of the processing liquid supplied at room temperature efficiently in shorter time to a target temperature, two or more cooling units 3 may be connected in series with each other, for example. In an example shown in FIG. 1, four cooling units 3 are disposed to the processing liquid supplier 1. In order to increase the quantity of the processing liquid to be cooled, two or more cooling units 3 may be connected in parallel. The cooling unit 3 will be described later in detail.

The pipe 22 branches on the downstream side with respect to the filter 227 into a pipe 23 and a pipe 24. A control valve 231 is interposed in the pipe 23, and a terminal of the pipe 23 is connected to the primary reservoir tank 51. Specifically, the pipes 22 and 23 function as a circulation flow path of causing the processing liquid to circulate with respect to the primary reservoir tank 51. As the feed pump 222 for feeding the processing liquid under pressure and the cooling unit 3 for cooling the processing liquid are interposed in the pipe 22, the processing liquid circulates through the circulation flow path to maintain the processing liquid in the primary reservoir tank 51 at a predetermined temperature lower than room temperature.

A control valve 241 is interposed in the other pipe 24, and a terminal of the pipe 24 is connected to a secondary reservoir tank 52. The cooled processing liquid passed through the pipe 24 flows into the secondary reservoir tank 52, and the secondary reservoir tank 52 stores the processing liquid therein.

Two-system pipes (feed pipes) 25 and 26 are connected to a lower part of the secondary reservoir tank 52. A feed pump 251, a temperature sensor 252, the cooling unit 3, a control valve 253, and the like are interposed in the pipe 25. Two cooling units 3 are connected in series. In addition to these units, functional units may be added appropriately, as needed, such as a flowmeter, a temperature sensor, and a pressure sensor, or some of the above units may be omitted. A terminal of the pipe 25 is connected to the substrate processor 9. The feed pump 251 feeds the processing liquid from the secondary reservoir tank 52 toward the downstream side under pressure. After the processing liquid is finally temperature-regulated at the two series-connected cooling units 3, 3, the processing liquid is fed to the substrate processor 9 through the control valve 253.

Likewise, a feed pump 261, a temperature sensor 262, the cooling units 3, a control valve 263, and the like are interposed in the pipe 26. In addition to these units, functional units may be added appropriately, as needed, such as a flowmeter, a temperature sensor, and a pressure sensor, or some of these units may be omitted. A terminal of the pipe 26 is connected to the substrate processor 9. The feed pump 261 feeds the processing liquid from the secondary reservoir tank 52 toward the downstream side under pressure. After the processing liquid is finally temperature-regulated at the two series-connected cooling units 3, 3, the processing liquid is fed to the substrate processor 9 through the control valve 263.

The substrate processor 9 and the secondary reservoir tank 52 are connected to each other through two-system pipes (return pipes) 27 and 28. A control valve 271 is interposed in the pipe 27. The processing liquid returning from the substrate processor 9 flows into the secondary reservoir tank 52 through the pipe 27. Likewise, a control valve 281 is interposed in the pipe 28. The processing liquid returning from the substrate processor 9 flows into the secondary reservoir tank 52 through the pipe 28.

As described above, the two-system feed pipes independent of each other and the two-system return pipes independent of each other are provided between the processing liquid supplier 1 and the substrate processor 9 as flow paths for causing the processing liquid to flow between the processing liquid supplier 1 and the substrate processor 9. More specifically, the processing liquid fed to the substrate processor 9 through the pipe 25 as a feed pipe is finally collected in the secondary reservoir tank 52 through the pipe 27 as a return pipe. The processing liquid fed to the substrate processor 9 through the pipe 26 as a feed pipe is finally collected in the secondary reservoir tank 52 through the pipe 28 as a return pipe.

Thus, each of two processing units provided independently of each other in the substrate processor 9 can be individually supplied with the processing liquid from the processing liquid supplier 1. As needed, these processing liquids may differ from each other in a temperature and a flow rate. In this example, the two feed systems are provided for supplying and collecting the processing liquid into and from the substrate processor 9, as described above. Meanwhile, the number of these systems may be changed, as appropriate, in response to a requirement on the side of the substrate processor 9.

Further, the feed pipe 25 is provided with a circulation pipe 255 branching from the feed pipe 25 on the upstream side with respect to the control valve 253, and a terminal of the circulation pipe 255 is connected to the return pipe 27. A control valve 256 is interposed in the circulation pipe 255. Likewise, the feed pipe 26 is provided with a circulation pipe 265 branching from the feed pipe 26 on the upstream side with respect to the control valve 263, and a terminal of the circulation pipe 265 is connected to the return pipe 28. A control valve 266 is interposed in the circulation pipe 265.

The feed pipe 25 and the return pipe 27 form a circulation flow path including the substrate processor 9, and the cooling units 3 are provided along the circulation flow path. This allows the processing liquid at a stable temperature to be fed to the substrate processor 9. By causing the processing liquid to circulate through the circulation pipe 255, it also becomes possible to cause the processing liquid to circulate inside the processing liquid supplier 1 without feeding the processing liquid to the substrate processor 9. This also applies to circulation between the feed pipe 26 and the return pipe 28.

The pipes and the functional units forming the pipe system 2 are each made of a resin material in a part to contact the processing liquid. As an example, fluorine resin such as perfluoroalkoxy alkane (PFA) resin or polytetra fluoroethylene (PTFE) resin is preferably applicable as a material not to cause release of impurity such as metal ions into the processing liquid.

FIG. 2 shows an exemplary configuration of the cooling unit. All the cooling units 3 provided along the pipe system 2 are based on the same principles. Meanwhile, the sizes (capacities) and cooling performances thereof are not always required to be the same but can be selected, as appropriate, in response to the temperature and flow rate of the processing liquid to be handled by each of the cooling units 3.

Main structures of the cooling unit 3 include a refrigerating circuit 31, a circulating liquid circuit 33, and the heat exchanger 35. A circuit already available as a product can be used as the refrigerating circuit 31. Thus, only a minimum configuration required for explanation of principles is shown in the drawings and the operation thereof will be described simply. Further, regarding a pressure sensor and a temperature sensor appropriately provided along the flow path as necessary, descriptions of these sensors will also be omitted.

In the cooling unit 3, a first cooling medium cooled by the refrigerating circuit 31 is used to cool a second cooling medium to circulate in the circulating liquid circuit 33, and the heat exchanger 35 cools the processing liquid using the second cooling medium thereby cooled. By doing so, the processing liquid is cooled to a desired cooling target temperature. Cooling the processing liquid in this way by the two-stage cooling process using the intervening circulating liquid circuit 33 is intended to eliminate metal to become a contamination source from the pipes and others to be touched by the DIW as the processing liquid, thereby outputting high-purity DIW.

The refrigerating circuit 31 is a so-called chiller, and includes a compressor (compression machine) 311, an air-cooled condenser 312, an evaporator 313, and a pipe 314 connecting these parts to form a circulation flow path. An appropriate cooling medium (first cooling medium) that may be chlorofluorocarbons or a substitute for chlorofluorocarbons, for example, is poured under a high pressure in the circulation flow path. The cooling medium compressed and pressurized by the compressor 311 and the air-cooled condenser 312 is vaporized by the evaporator 313. During the vaporization, heat is drawn from the surrounding to cool a target. Here, a cooling target is the second cooling medium poured in the circulating liquid circuit 33.

A fan motor 315 is arranged near the air-cooled condenser 312, and dissipates heat of condensation generated by the first cooling medium to the outside. While not shown in the drawings, functional units including an expansion valve, a pressure sensor, and a temperature sensor are provided at appropriate positions in the refrigerating circuit 31.

The circulating liquid circuit 33 feeds the cooling medium (second cooling medium) having been cooled by the refrigerating circuit 31 to the heat exchanger 35 in the next stage. For this purpose, the circulating liquid circuit 33 has a configuration where a reservoir tank 331, a feed pump 332, control valves 333, 335, and 336, a flowmeter 334 and the like are interposed in a pipe 34. More specifically, the pipe 34 includes a pipe 341 forming connection between a lower part of the reservoir tank 331 and an input port 352 of the heat exchanger 35, a pipe 342 forming connection between an output port 353 of the heat exchanger 35 and the evaporator 313, a pipe 343 forming connection between the pipe 341 and the pipe 342, and a pipe 344 forming connection between the evaporator 313 and the reservoir tank 331.

The feed pump 332, the control valve 333, and the flowmeter 334 are interposed in the pipe 341. The control valve 336 is interposed in the pipe 342. The pipe 343 is provided in such a way as to form connection between the downstream side of the pipe 341 with respect to the flowmeter 334 and the downstream side of the pipe 342 with respect to the control valve 336, and the control valve 335 is provided along a flow path in the pipe 343.

When the feed pump 332 feeds the cooling medium under pressure and the control valve 333 is opened in response to a control command from the controller 8, the cooling medium fed from the reservoir tank 331 is supplied to the heat exchanger 35. By opening the control valve 336, the cooling medium returning from the heat exchanger 35 is allowed to be received in the pipe 342. By opening the control valve 335, the cooling medium fed by the feed pump 332 is allowed to flow at least partially or entirely into the pipe 342 while bypassing the heat exchanger 35.

As will be described later, in this embodiment, the circulating liquid circuit 33 causes the cooling medium at a constant temperature and a constant flow rate to circulate therein. The cooling medium thus cooled is distributed between the heat exchanger 35 and the pipe 343 at a predetermined flow rate ratio, thereby controlling the temperature of the processing liquid (DIW) to be output from the heat exchanger 35.

The cooling medium having flowed from the heat exchanger 35 and the pipe 343 into the pipe 342 flows back into the reservoir tank 331 through the evaporator 313 and the pipe 344. In this way, a flow path for causing the cooling medium (second cooling medium) to circulate from the reservoir tank 331 through the evaporator 313 is formed in the circulating liquid circuit 33, and the second cooling medium cooled by the evaporator 313 circulates in the circulating liquid circuit 33. As a result, the temperature of the circulating cooling medium is stabilized.

A pressure sensor 337 and a temperature sensor 338 are provided on the downstream side of the pipe 341 with respect to the feed pump 332. An additional temperature sensor 339 is provided on the downstream side of the pipe 342 with respect to a point of merging with the pipe 343. The controller 8 controls the feed pump 332 and the control valves 333, 335 and 336 on the basis of output signals from these sensors, thereby feeding the cooling medium at a predetermined temperature and a predetermined flow rate into the heat exchanger 35.

A liquid to be used as the second cooling medium is a liquid coolable to a lower temperature than a final cooling target temperature of the processing liquid (in this example, 5° C. and this temperature will be called a “final target temperature”) without being coagulated by freezing. For example, ethylene glycol (EG) having a melting point of minus 13° C. or an aqueous solution thereof is preferably available. Regarding the temperature of the second cooling medium, the second cooling medium is maintained at a lower temperature than the target temperature of the processing liquid to be output from the cooling unit 3.

As will be described later in detail, the heat exchanger 35 includes an input port 355a for DIW for receiving the processing liquid (DIW) to be cooled, an output port 356a for outputting the cooled DIW, the input port 352 for cooling medium for receiving the second cooling medium, and the output port 353 for discharging the cooling medium.

The DIW to be cooled is input to the input port 355a. A pipe 375 bypassing the heat exchanger 35 is provided between the input port 355a and the output port 356a of the heat exchanger 35, and a control valve 376 is interposed in the pipe 375. Opening the control valve 376 as needed allows the heat exchanger 35 to be bypassed. If the temperature of the DIW to be input is already lower than a target temperature, for example, it is possible to avoid further temperature reduction by bypassing the heat exchanger 35.

A temperature sensor 378 is provided on the output side of the heat exchanger 35, more specifically, on the downstream side with respect to a merging point between output from the heat exchanger 35 and output from the pipe 375. This causes the temperature sensor 378 to detect the temperature of the cooled DIW output from the heat exchanger 35 or the temperature of the uncooled DIW flowing in after bypassing the heat exchanger 35.

As needed, two or more cooling unit 3 having the above configuration are provided along the flow path. In this embodiment, four cooling units 3 are connected in series along the pipe 22. Two cooling units 3 are further connected in series along each of the pipes 25 and 26. As shown in FIG. 1, the temperature sensor 224 is provided on the input side of the most-upstream cooling unit 3 among the plurality of cooling units 3 connected in series along the pipe 22, namely, on the upstream side with respect to the most-upstream cooling unit 3. The temperature sensors 252 and 262 are further provided along the pipes 25 and 26 respectively.

As shown in FIG. 2, at each of the cooling units 3, the temperature sensor 378 is provided at an output part of the cooling unit 3, more specifically, at the merging point between output from the heat exchanger 35 and output from the pipe 375. The temperature sensor 378 detects the temperature of the DIW output from the corresponding cooling unit 3. Meanwhile, from the viewpoint of a different cooling unit 3 provided in a next stage, namely, provided next to and on the downstream side with respect to the corresponding cooling unit 3, the temperature sensor 378 detects the temperature of the DIW to be input to this different cooling unit 3. In this way, the temperature sensor is provided on each of the input side and the output side of each heat exchanger 35.

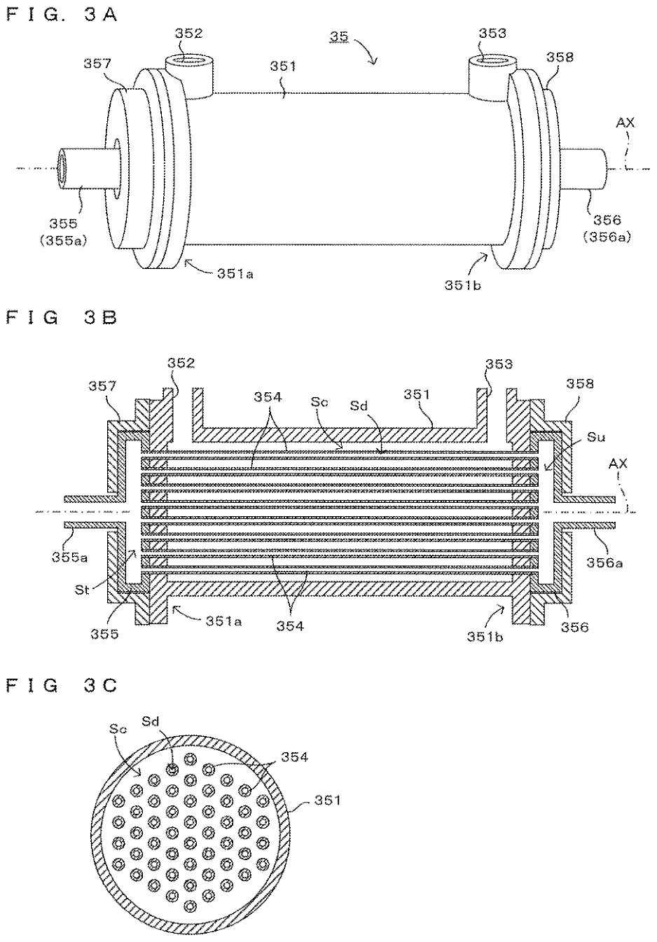

FIGS. 3A to 3C show an exemplary configuration of the heat exchanger. More specifically, FIG. 3A shows the appearance of the heat exchanger 35. In FIG. 3A, a dash-dot line shows a virtual center axis AX of the heat exchanger 35. FIG. 3B is a longitudinal sectional view showing a section of the heat exchanger 35 along the center axis AX. FIG. 3C is a cross sectional view showing a section perpendicular to the center axis AX.

The heat exchanger 35 includes a housing 351 having a substantially circular columnar outer shape with a hollow interior extending along the center axis AX, in other words, having a circular cylindrical shape with closed opposite ends. The housing 351 has a side surface where the input port 352 is provided at a position close to one edge 351a of the housing 351, and the output port 353 is provided at a position close to the other edge 351b of the housing 351 opposite to the one edge 351a. The cooling medium fed from the circulating liquid circuit 33 flows through the input port 352 into an internal space defined by an inner wall of the housing 351, and flows out through the output port 353. The cooling medium having flowed into the internal space of the housing 351 fills an external side of an inner pipe inserted in and passed through the internal space and used for causing the DIW to flow therein. In the internal space of the housing 351, a space except the inner pipe and except a space in the inner pipe is called a current space Sc. The cooling medium supplied from the circulating liquid circuit 33 to the heat exchanger 35 flows in the current space Sc.

The housing 351 includes a plurality of inner pipes 354 inserted in and passed through the housing 351 and penetrating the current space Sc from the one edge 351a to the other edge 351b of the housing 351. On the side of the one edge 351a, the inner pipe 354 is terminated by a terminal member 355 and an internal space Sd of the inner pipe 354 communicates with an internal space St of the terminal member 355. Likewise, on the side of the other edge 351b, the inner pipe 354 is terminated by a terminal member 356 and the internal space Sd of the inner pipe 354 communicates with an internal space Su of the terminal member 356. As a result, the respective internal spaces St and Su of the terminal members 355 and 356 communicate with each other via the internal space Sd of the inner pipe 354.

An input port 355a for receiving the DIW to be cooled is provided at an end of the terminal member 355. An output port 356a for feeding the DIW is provided at an end of the terminal member 356. The input port 355a connects to one end of each of the inner pipes 354, and the other end of each inner pipe 354 connects to the output port 356a. Thus, the inner pipes 354 have a parallel relationship with each other in terms of a flow path of the DIW. The DIW having flowed into the internal space St from the input port 355a branches into flows to enter the inner pipes 354, passes through the internal space Sd of each inner pipe 354 to flow out into the internal space Su, and is then fed through the output port 356a toward the downstream side with respect to the heat exchanger 35. Specifically, the terminal member 355 and the inner pipes 354 function as a manifold for branching the DIW, and the inner pipes 354 and the terminal member 356 function as a manifold for merging the flows of the DIW.

In the following, if the input port 355a and the input port 352 are required to be distinguished from each other, they will be called an “input port 355a for DIW” and an “input port 352 for cooling medium.” Likewise, if the output port 356a and the output port 353 are required to be distinguished from each other, they will be called an “output port 356a for DIW” and an “output port 353 for cooling medium.”

The inner pipe 354 and the terminal members 355 and 356 are made of resin materials not to cause release of impurity such as metal ions. Like the other pipes, the inner pipe 354 and the terminal members 355 and 356 are formed by using a material that is preferably a fluorine resin material such as PFA resin, for example. As an example, a PFA tube is available as the inner pipe 354. Regarding the terminal members 355 and 356 each required to be processed into a complicated shape, PTFE resin is available in addition to PFA resin. The terminal members 355 and 356 can be formed into the same shape.

The terminal members 355 and 356 are fixed to the housing 351 by cover members 357 and 358 respectively. Specifically, the terminal member 355 is mounted on the one edge 351a of the housing 351 in such a way as to be interposed between the one edge 351a of the housing 351 and the cover member 357. Likewise, the terminal member 356 is mounted on the other edge 351b of the housing 351 in such a way as to be interposed between the other edge 351b of the housing 351 and the cover member 358. The cover members 357 and 358 can be formed into the same shape.

The housing 351 and the cover members 357 and 358 are each made of metal such as stainless steel, for example, and are coupled to each other with coupling members such as bolts not shown in the drawings. As will be described later, while each of the cooling medium and the DIW is supplied to the heat exchanger 35 in a pressurized state, forming the housing 351 using solid metal provides resistance to such a pressure. The resin terminal members 355 and 356 themselves do not have high resistances to such a pressure. However, reinforcing the terminal members 355 and 356 from outside using the cover members 357 and 358 allows the terminal members 355 and 356 to be resistant to such a pressure.

The current space Sc and the internal space Sd of the inner pipe 354 are separated from each other by a pipe wall of the inner pipe 354, and the cooling medium flowing in the current space Sc and the DIW flowing in the internal space Sd are separated from each other. An outer surface of the pipe wall touches the cooling medium at a low temperature. Thus, the DIW is cooled through heat exchange with the cooling medium across the pipe wall, and is output from the output port 356a at a lower temperature than the temperature of the DIW during input from the input port 355a. As the inner pipes 354 are inserted in and passed through the interior of the housing 351, the DIW is cooled at high efficiency. Here, the cooling medium and the DIW flow in the same direction (in FIG. 3A, toward the right) in the heat exchanger 35. Meanwhile, the flow direction of the cooling medium and the flow direction of the DIW may be reversed by switching the input and output of the cooling medium, for example.

If the cooling units 3 are connected in multiple stages, a cooling target temperature at each cooling unit 3 is not required to be the final target temperature. Specifically, in a configuration of bringing the DIW to the final target temperature stepwise using the cooling units 3 in multiple stages, a temperature reduction required to be attained in each cooling unit 3 can be smaller. In this case, each of the temperature of the DIW to be input and the temperature of the DIW to be output differs between the cooling devices 3, so that the cooling units 3 are not always required to be the same in terms of respective configurations and specifications.

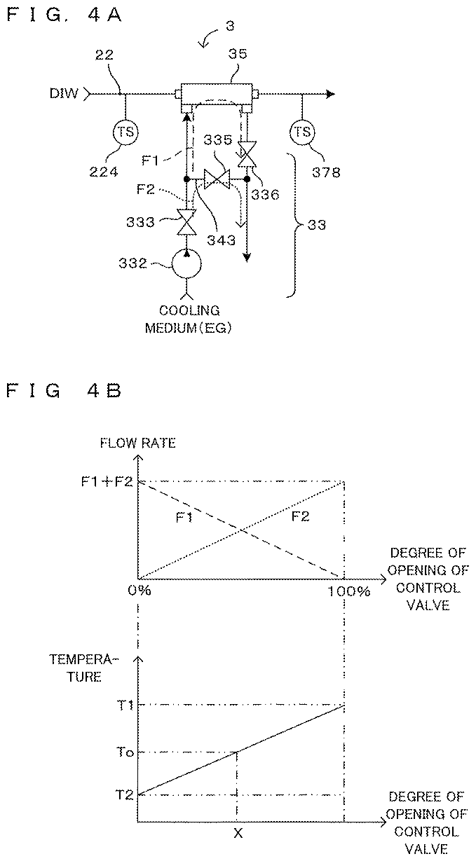

A specific configuration of temperature regulation on the processing liquid using the cooling unit 3 will be described next. For explanation of principles, a temperature regulating method implemented in the single cooling unit 3 will be described by referring to FIGS. 4A and 4B. While the most-upstream cooling unit 3 provided along the pipe 22 is described here as an example, the cooling units 3 at different positions operate in the same way.

FIGS. 4A and 4B explain temperature regulating operation at the cooling unit. More specifically, FIG. 4A schematically shows the configuration of the cooling unit 3, and FIG. 4B shows a relationship between a degree of opening of the control valve and a DIW temperature in the circulating liquid circuit 33. In FIG. 4A, a dashed arrow shows a flow of the cooling medium fed from the feed pump 332 and input to the heat exchanger 35, and the flow rate thereof is indicated by a sign F1. A dotted arrow shows a flow of the cooling medium not to pass through the heat exchanger 35 by being bypassed through the pipe 343, and the flow rate thereof is indicated by a sign F2.

The feed pump 332 feeds the cooling medium always at a constant temperature and a constant flow rate. The cooling medium fed at the constant flow rate is distributed between the heat exchanger 35 and the pipe 343, and a flow rate ratio therebetween is determined by degrees of opening of the control valves 335 and 336. An entire flow rate (F1+F2) is constant independent of degrees of opening of the control valves 335 and 336.

The control valves 335 and 336 are flow rate regulating valves, and degrees of opening thereof are regulated complementarily to each other by the controller 8. That is, when a degree of opening of the control valve 335 is 100%, a degree of opening of the control valve 336 is 0%. As a degree of opening of the control valve 335 becomes smaller, a degree of opening of the control valve 336 increases. When a degree of opening of the control valve 335 finally becomes 0%, a degree of opening of the control valve 336 becomes 100%.

The temperature of the DIW to be input to the heat exchanger 35 and detected by the temperature sensor 224 is indicated by a sign T1. The temperature of the DIW output from the heat exchanger 35 and detected by the temperature sensor 378 is indicated by a sign To.

In FIG. 4B, a horizontal axis is defined by a degree of opening of the control valve 335. As described above, when a degree of opening of the control valve 335 changes from 0% to 100%, a degree of opening of the control valve 336 changes complementarily from 100% to 0% while description thereof will be omitted. As shown in the upper graph of FIG. 4B, when a degree of opening of the control valve 335 is 0%, the cooling medium entirely flows into the heat exchanger 35. Thus, the DIW is output at lowest temperature from the heat exchanger 35 in this case, and this temperature is indicated by a sign T2.

While the flow rate F1 is reduced in response to increase in a degree of opening of the control valve 335 from 0%, the flow rate F2 increases. In response to reduction in the quantity of the cooling medium flowing into the heat exchanger 35, the temperature of the DIW output from the heat exchanger 35 increases. When a degree of opening of the control valve 335 becomes 100%, the cooling medium does not flow into the heat exchanger 35. Thus, the temperature of the DIW becomes the temperature T1, which is equal to the temperature of the DIW at the time of input. While a degree of opening of the control valve 335 and the temperature of the DIW are described as having a linear relationship for the explanation of the principles herein, this relationship does not always apply. However, the temperature of the DIW output from the heat exchanger 35 still has the tendency to increase monotonously in response to increase in a degree of opening of the control valve 335.

Thus, with a degree of opening of the control valve 335 at an arbitrary value X, the temperature To of the DIW may assume any value between the temperature T2 and the temperature T1. Specifically, regulating a degree of opening of the control valve 335 (and that of the control valve 336) allows implementation of the temperature regulation on the DIW.

In order for the temperature of the DIW to be output to become a target temperature set in advance, the temperature T2 of the DIW to be output in response to input of the cooling medium in its entirety to the heat exchanger 35 is required to be lower than the target temperature. The temperature and flow rate of the cooling medium to circulate in the circulating liquid circuit 33 are set in such a way as to fulfill this condition. The operating condition in the circulating liquid circuit 33 set in this way is not changed during subsequent operation. That is, the circulating liquid circuit 33 is simply required to fulfill the function of feeding the cooling medium at a constant temperature and a constant flow rate, and even the low responsiveness thereof does not cause any problem in the temperature regulation on the DIW.

According to the above temperature regulating method, the cooling performance of the heat exchanger 35 changes readily in response to increase or reduction in the flow rate of the cooling medium, and this further changes the temperature of the DIW. To be more strict, while time delay responsive to the heat capacity of the heat exchanger 35 itself is caused, this delay is sufficiently smaller than response delay resulting from the heat capacity of the circulating liquid circuit 33 occurring when the temperature of the cooling medium is changed. Furthermore, the temperature of the DIW can be regulated steplessly using degrees of opening of the control valves 335 and 336, as described above.

Thus, as long as detection of the temperature of the DIW by the temperature sensor 378 and regulation of degrees of opening of the control valves 335 and 336 based on result of the temperature detection are conducted in a sufficiently short control cycle, it is possible to control the temperature To of the DIW to be output from the cooling unit 3 with excellent controllability and stability. Particularly, the temperature of the DIW can be increased readily if the temperature To thereof falls below a target temperature. This characteristic works advantageously as it can prevent freezing of the DIW reliably even if the target temperature is set to a temperature approximate to a freezing point.

The above temperature regulation can be implemented in each of the cooling units 3 connected in series. In particular, when the temperature of the DIW to be cooled is sufficiently higher than a final target temperature at the time of start of the processing liquid supplier 1, for example, the temperature of the DIW can be lowered in a short time by combining the respective cooling performances of the cooling units 3. On the other hand, if the temperature of the DIW to be input is reduced sufficiently in advance, the cooling units 3 connected in series are simply required to provide cooling performance as a whole to such an extent as will compensate for temperature increase of the DIW, and all of the cooling units 3 are not always required to operate. For example, it is possible to maintain the temperature of the DIW already cooled by operating only one or two cooling units 3 among the plurality of cooling units 3 connected in series and located on the downstream side in the line of the cooling units 3.

The above temperature regulation may be achieved, for example, by setting a target temperature in such a way that, among the plurality of cooling units 3 connected in series, the target temperature becomes higher at the cooling unit 3 closer to the upstream side and becomes lower at the cooling unit 3 closer to the downstream side. Then, by setting the target temperature at the most-downstream cooling unit 3 to the temperature of the DIW to be attained finally, it becomes possible to output the DIW at a requested temperature stably.

By doing so, in a situation where the temperature of the DIW is higher than the target temperature, all the cooling units 3 operate to cool the DIW to the target temperature. On the other hand, if the temperature of the DIW to be input is already lower than the target temperature, the corresponding cooling unit 3 outputs the DIW without cooling the DIW further. As a result, the DIW is prevented from being cooled excessively. As an example, the target temperature at the most-downstream cooling unit 3 is set to a final target temperature, and the target temperature at the one next cooling unit 3 on the upstream side with respect to the most-downstream cooling unit 3 is set to a temperature higher than the final target temperature by a degree from about 1 to 2° C. In this case, the most-downstream cooling unit 3 only has to conduct temperature regulation in a range from about 1 to 2° C., so that temperature variation of the DIW to be finally output can be limited to about 1° C. This further avoids the problem of freezing of the DIW due to excessive temperature reduction.

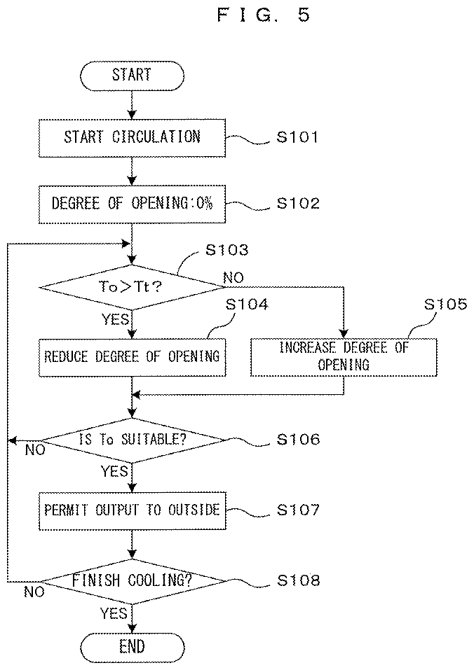

FIG. 5 is a flowchart showing the substance of a temperature regulating process according to this embodiment. To realized this process, the controller 8 executes the control program prepared in advance, thereby causing each unit of the apparatus to perform predetermined operation. First, circulation of the DIW to be cooled is started (step S101). Specifically, the DIW having been supplied from the outside through the pipe 21 and stored in the primary reservoir tank 51 is caused to circulate along the circulation flow path through the pipes 22 and 23. More specifically, the control valve 226 along the pipe 22 and the control valve 231 along the pipe 23 are opened, and the feed pump 222 feeds the DIW at a constant flow rate, thereby causing the DIW to circulate in the circulation flow path along which the DIW returns from the primary reservoir tank 51 to the primary reservoir tank 51 through the pipes 22 and 23.

At an initial stage of the process, a degree of opening of the control valve 335 at each cooling unit 3 is set to 0%, namely, the control valve 335 is closed (step S102). On the other hand, a degree of opening of the control valve 336 at this stage is 100%. Thus, the cooling medium fed from the feed pump 332 entirely flows into the heat exchanger 35 to cool the DIW through heat exchange with the cooling medium. Passing the DIW through the plurality of cooling units 3 reduces the temperature of the DIW stepwise.

The temperature To of the DIW output from the cooling unit 3 is detected by the temperature sensor 378, and is compared with a target temperature Tt set in advance (step S103). Here, the target temperature Tt is set individually for each of the plurality of cooling units 3. As described above, the target temperature Tt is set lower at the cooling unit 3 closer to the downstream side, and the target temperature Tt at the most-downstream cooling unit 3 is set to a final target temperature (5° C., for example).

If the temperature To of the DIW is higher than the target temperature Tt (YES in step S103), a degree of opening of the control valve 335 is reduced (step S104). This increases the ratio of the cooling medium to pass through the heat exchanger 35 to increase the cooling performance of the heat exchanger 35, thereby reducing the temperature of the DIW. On the other hand, if the temperature To of the DIW is lower than the target temperature Tt (NO in step S103), a degree of opening of the control valve 335 is increased (step S105). This reduces the quantity of the cooling medium to flow into the heat exchanger 35, thereby increasing the temperature of the DIW.

The above process is continued (NO in step S106) until the temperature To of the DIW output from the most-downstream cooling unit 3 becomes a temperature suitable for output to the outside. If this condition is fulfilled (YES in step S106), output to the outside is permitted (step S107). As a result, it becomes possible to transfer the DIW to the secondary reservoir tank 52 thereafter by opening the control valve 241 along the pipe 24. The temperature of the DIW to be output at this stage is substantially equal to the final target temperature.

Even after output to the outside is permitted, circulation of the DIW and the temperature regulation for each cooling unit 3 described above are still performed continuously until it is judged that the cooling may be finished (step S108). By doing so, the cooled DIW is gradually accumulated in the primary reservoir tank 51, and the DIW cooled sufficiently is caused to circulate through the circulation flow path. Finally, a degree of opening of the control valve 376 is regulated individually in response to the target temperature set for each cooling unit 3 and a detected temperature, thereby making preparation for supplying the processing liquid at a predetermined temperature immediately in response to a request while preventing freezing of the DIW due to excessive cooling.

The DIW cooled in this way is assumed to be increased in temperature while the DIW flows through the pipe system 2 after passing through the pipe 24. In response to this, final temperature regulation is conducted using the cooling units 3 interposed in the pipes 25 and 26 immediately before feeding into the substrate processor 9. Each of these pipes is also provided with the plurality of (more specifically, two) cooling units 3 connected in series. By regulating a degree of opening of the control valve 376 in response to result of temperature detection on the basis of principles same as those described above, it becomes possible to feed the DIW regulated at a desired temperature to the substrate processor 9.

As described above, in this embodiment, the cooling unit 3 provided along the flow path cools the DIW as the cooling target processing liquid. This is achieved by the temperature regulating method by which the cooling medium at a constant temperature and a constant flow rate is distributed between the flow path passing through the heat exchanger 35 and the flow path bypassing the heat exchanger 35, and a ratio between the respective flow rates is regulated using temperature detection result about the DIW output from the cooling unit 3.

In this way of control, while the cooling medium circulating in the circulating liquid circuit 33 is branched into two flow paths in a part of the flow path, the temperature and flow rate themselves of the cooling medium do not change. Thus, low responsiveness at the refrigerating circuit 31 and the circulating liquid circuit 33 does not affect temperature regulation on the processing liquid. Meanwhile, the cooling performance of the heat exchanger 35 can be changed steplessly in a wide range by regulating the quantity of the cooling medium to flow into the heat exchanger 35. This is achieved only by generating a change in a flow rate ratio resulting from the operations of the control valves 335 and 336. As a result, in this embodiment, it is possible to output the DIW cooled to a desired temperature with excellent controllability and stability. Thus, even if a target temperature is a temperature approximate to a freezing point, it is still possible to prevent freezing of the DIW.

### Second Embodiment

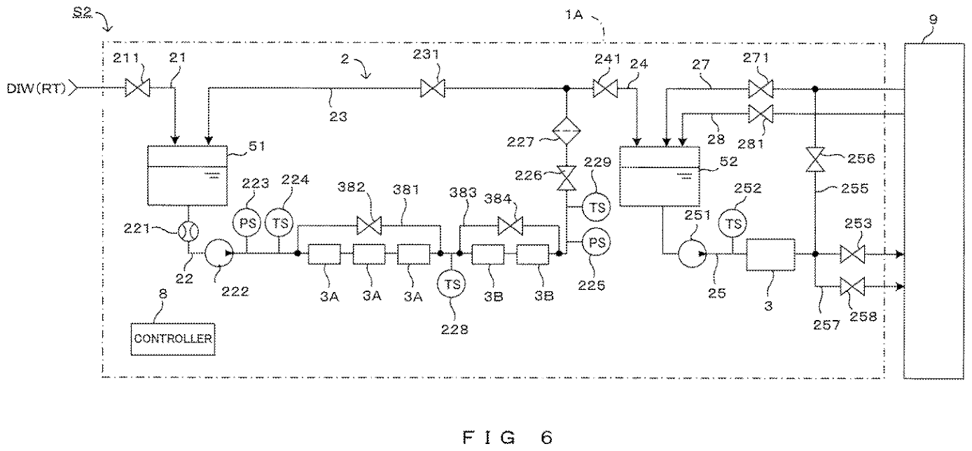

FIG. 6 shows a schematic configuration of a second embodiment of a substrate processing system including a cooling apparatus according to the present invention. The configuration and operation of a substrate processing system S2 according to the second embodiment are basically the same as those of the first embodiment, and differs only in the following point. Here, a structure having the same configuration and fulfilling the same function as that of the first embodiment is given the same sign and description thereof is omitted, and the difference from the first embodiment is mainly described.

The substrate processing system S2 of the second embodiment differs from the substrate processing system S of the first embodiment mainly in the arrangement of the cooling unit. A processing liquid supplier 1A of this embodiment includes cooling units 3A and 3B each configured by removing the bypass pipe 375, the control valve 376, and the temperature sensor 378 from the cooling unit 3 shown in FIG. 2, and the pipe 22 is provided with a plurality of the cooling units 3A and 3B (in this example, five) connected in series. While the cooling unit 3A and the cooling unit 3B have the same configuration, they are given the different signs in order to be distinguished from each other in the following description.

A pipe 381 is provided to collectively bypass three cooling units 3A on the upstream side among the above cooling units, and a control valve 382 is interposed in the pipe 381. A temperature sensor 228 is provided in the pipe 22 after merging with the pipe 381. A pipe 383 is provided to collectively bypass two cooling units 3B on the downstream side, and a control valve 384 is interposed in the pipe 383. A temperature sensor 229 is provided on the further downstream side.

A configuration on the downstream side with respect to the secondary reservoir tank 52 is also changed. Specifically, the pipe 26 and the accompanying elements including the feed pump 261 and the temperature sensor 262 are omitted. Alternatively, the DIW is fed from a pipe 257 branching from the pipe 25 to the substrate processor 9 through a control valve 258. Only one cooling unit 3 is provided along the pipe 25. Note that the configuration on the downstream side with respect to the secondary reservoir tank 52 may be the same as that of the first embodiment.

This embodiment largely differs from the first embodiment in that the three cooling units 3A are, as a whole, handled as one cooling unit, and the two cooling units 3B are, as a whole, handled as one cooling unit. In this case, temperature regulation on the DIW is conducted as follows.

Specifically, at the three upstream cooling units 3A, degrees of opening of the respective control valves 335 and 336 are regulated in an interlocked relationship between the cooling units 3A. The temperature of the DIW output from the most-downstream cooling unit 3A among these cooling units 3A is detected by the temperature sensor 228, and degrees of opening of the respective control valves 335 and 336 are regulated uniformly at the three cooling units 3A in response to result of the detection. By doing so, the three cooling units 3A operate integrally and temperatures output therefrom are maintained at a target temperature. Likewise, the two downstream cooling units 3B are controlled integrally. The specific substance of the control follows the same principles as those described above. Note that, if the temperature of the DIW to be input is already lower than the target temperature, the cooling unit is bypassed by opening the control valve 382 or 384, as appropriate.

The following describes main advantages fulfilled by the above temperature regulation conducted by controlling the plurality of cooling units collectively. First, the number of control valves to be controlled is reduced, thereby achieving the control more simply and reducing the occurrence of interference between regulation results obtained at corresponding stages. Furthermore, reducing a parts count makes it possible to encourage reduction in the cost of the apparatus and reduction in resource consumption.

The configuration of the cooling unit 3 along the pipe 25 can be the same as that of the first embodiment, and temperature regulation at this cooling unit 3 can be conducted on the basis of the principles shown in FIGS. 4A and 4B.

### Modifications

In addition to the two embodiments described above, an embodiment intermediary between these embodiments may be devised. As an example, in the substrate processing system S of the first embodiment shown in FIG. 1, temperature regulation is conducted individually at each of the four cooling units 3 along the pipe 22. These cooling units 3 may be replaced by the cooling units 3A of the second embodiment, the cooling units 3A may be divided into two on the upstream side and two on the downstream side, and each of the two upstream cooling units 3A and the two downstream cooling units 3A may conduct temperature regulation collectively, for example. The number of the cooling units provided in these embodiments is not limited to those illustrated in the drawings but may be increased or reduced, as appropriate.

### Others

As seen from the foregoing, in the above embodiments, the substrate processing systems S and S2 correspond to a “substrate processing apparatus” of the present invention, and the processing liquid supplier 1 and the substrate processor 9 function as a “cooling part” and a “substrate processor” of the present invention respectively. The pipes 25 and 26 connecting these units correspond to a “supply pipe” of the present invention.

Regarding the processing liquid suppliers 1 and 1A of the above embodiments, the heat exchanger 35 and the temperature sensor 378 function as a “heat exchanger” and a “temperature detector” of the present invention respectively, and the refrigerating circuit 31 and the circulating liquid circuit 33 integrally function as a “cooling medium output part” and a “cooling medium supply source” of the present invention. Regarding the pipe 34 in the circulating liquid circuit 33, the pipes 341, 342, and 344 integrally function as a “supply flow path former” of the present invention, and the pipe 343 functions as a “bypass flow path former” of the present invention.

In the above embodiments, the primary reservoir tank 51 functions as a “reservoir tank” of the present invention, and the pipes 23 and 24 function as a “circulation flow path former” of the present invention. The secondary reservoir tank 52 also corresponds to the “reservoir tank” of the present invention, and the pipes 25, 26, 27, and 28 function as the “circulation flow path former” of the present invention. Further, the pipe 21 corresponds to an “introduction pipe” of the present invention.

Note that the invention is not limited to the above embodiment, and various changes other than the aforementioned ones can be made without departing from the gist of the invention. For example, some examples of the number of the cooling units provided along the pipe system are given in the above description. However, the number of the cooling units or the entire configuration of the pipe system is not limited to that shown above but is determined freely.

Further, in the above embodiments, the cooling unit used for cooling the processing liquid has a configuration where the second cooling medium is cooled using the first cooling medium, and the processing liquid is cooled using the second cooling medium. However, as long as the principles of cooling the processing liquid through heat exchange with the cooling medium, the specific configuration thereof is not limited to the above but is determined freely. Further, the configuration of the heat exchanger is also not limited to that shown in FIG. 3 but various configurations are applicable. Furthermore, the processing liquid supplier 1 of the above embodiment includes the refrigerating circuit 31 and the circulating liquid circuit 33 as the “cooling medium output part” of the present invention. However, it may alternatively be configured to operate in response to supply of the cooling medium from an external cooling medium supply source configured to output the cooling medium at a constant temperature and a constant flow rate.

Further, in the temperature regulating process (FIG. 5) of the above embodiments, a degree of opening of the control valve is changed in response to whether the temperature of the processing liquid is higher or lower than the target temperature Tt. However, the target temperature is not required to be a single numerical value but may be defined as a certain temperature range, for example.

Further, in the above embodiments, the processing liquid to be cooled is the DIW. However, the composition or temperature of the processing liquid is not limited to this but is determined freely. For example, the present invention is further applicable to the purpose of cooling each type of chemical, an organic solvent, etc. to be used in processing a substrate. In this case, a material of the pipe is appropriately selectable in response to the property of the processing liquid. If the purity of the processing liquid is not a significant matter, for example, the inner pipe of the heat exchanger may be made of metal from the viewpoint of cooling efficiency. Furthermore, the purpose of use of the processing liquid is also not limited to substrate process but is determined freely.

As has been described above by providing the exemplary specific embodiments, in the cooling apparatus according to the present invention, the temperature and flow rate of the cooling medium to be output from the cooling medium output part may be configured to be constant independently of a flow rate ratio. In this configuration, the cooling medium output part is simply required to be capable of outputting the cooling medium at the constant temperature and the constant flow rate. Thus, the responsiveness of the cooling medium output part itself does not affect temperature regulation on the processing liquid.

Further, for example, the flow rate of the processing liquid to flow into the heat exchanger may be constant. This configuration does not generate variation in the quantity of the processing liquid to be cooled, specifically, results in a constant load. This makes it possible to control the temperature of the processing liquid with excellent controllability and stability.

Further, for example, the cooling apparatus may include a plurality of the heat exchangers connected in series with each other, and a plurality of the cooling medium output parts provided in response to corresponding ones of the heat exchangers. In this configuration, by cooling the processing liquid stepwise using the plurality of heat exchangers, it becomes possible to reduce the temperature of the processing liquid largely in a short time. In this case, the temperature detector may be configured to detect the temperature of the processing liquid output from the heat exchanger on the most-downstream side among the plurality of heat exchangers, and the controller may be configured to regulate the flow rate ratio collectively for the plurality of cooling medium output parts on the basis of detection result from the temperature detector. As another example, a plurality of the temperature detectors configured to individually detect the temperatures of the processing liquid output from corresponding ones of the plurality of heat exchangers may be provided, and the controller may be configured to regulate the respective flow rate ratios for the cooling medium output parts on the basis of temperature detection results about the processing liquid output from the corresponding heat exchangers. In each of these configurations, it is possible to control a final temperature of the processing liquid stably with excellent controllability.

Further, for example, the cooling apparatus of the present invention may include the reservoir tank configured to store the processing liquid, and the circulation flow path former configured to form the circulation flow path for supplying the processing liquid from the reservoir tank to the heat exchanger and causing the processing liquid to flow from the heat exchanger back into the reservoir tank. In this configuration, by causing the processing liquid to circulate while cooling the processing liquid, it becomes possible to store the processing liquid in a sufficiently cooled state. Moreover, the temperature of the processing liquid to be input to the heat exchanger is reduced in response to the circulation. This eliminates the need for the heat exchanger to reduce the temperature of the processing liquid largely, thereby providing improved temperature stability.

In this case, the introduction pipe for introducing the processing liquid not temperature regulated into the reservoir tank may be connected to the reservoir tank. In this configuration, the processing liquid having been consumed by being output to the outside can be replenished from the outside. Even if this causes temporary increase in a temperature inside the reservoir tank, it is still possible to recover a low-temperature state by causing the processing liquid to circulate through the heat exchanger.

De-ionized water or pure water is available as the processing liquid of the present invention, for example. Water is a liquid with a large specific heat. Thus, it is difficult to regulate the temperature without freezing the processing liquid, especially in a temperature range approximate to a freezing point thereof. According to the present invention, a flow rate of the cooling medium entering the heat exchanger, out of the cooling medium output at a constant temperature and constant flow rate, is adjusted. Therefore, it is possible to control the temperature of the processing liquid stably with excellent controllability even in such a temperature range.

This invention is applicable to every type of technique of cooling a processing liquid. In particular, this invention is preferable in a field where the processing liquid is required to be cooled to a temperature approximate to a freezing point thereof without being frozen.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A cooling apparatus to cool and output a processing liquid, the cooling apparatus comprising:
a cooling medium output part which outputs the cooling medium;
a heat exchanger which cools the processing liquid through heat exchange with the cooling medium;
a supply flow path former which forms a cooling medium supply flow path for causing the cooling medium to circulate between the cooling medium output part and the heat exchanger;
a bypass flow path former which forms a bypass flow path for returning the cooling medium output from the cooling medium output part to the cooling medium output part without passing the cooling medium through the heat exchanger;
a temperature detector which detects the temperature of the processing liquid output from the heat exchanger; and
a controller which controls the temperature of the processing liquid to be output from the heat exchanger by regulating a flow rate ratio of the cooling medium to flow in each of the cooling medium supply flow path and the bypass flow path on a basis of detection result from the temperature detector.

2. The cooling apparatus according to claim 1, wherein the temperature and flow rate of the cooling medium to be output from the cooling medium output part are constant independently of the flow rate ratio.

3. The cooling apparatus according to claim 1, wherein the flow rate of the processing liquid to flow into the heat exchanger is constant.

4. The cooling apparatus according to claim 1, further comprising:
a plurality of the heat exchangers connected in series with each other; and
a plurality of the cooling medium output parts provided in response to corresponding ones of the heat exchangers, wherein
the temperature detector detects the temperature of the processing liquid output from the heat exchanger on most-downstream side among the plurality of heat exchangers, and the controller is configured to regulate the flow rate ratio collectively for the plurality of the cooling medium output parts on the basis of detection result from the temperature detector.

5. The cooling apparatus according to claim 1, further comprising:
a plurality of the heat exchangers connected in series with each other;
a plurality of the cooling medium output part provided in response to corresponding ones of the heat exchangers; and;
a plurality of the temperature detectors individually detect the temperatures of the processing liquid output from corresponding ones of the plurality of heat exchangers, wherein
the controller regulates the respective flow rate ratios for the cooling medium output parts on the basis of temperature detection results about the processing liquid output from the corresponding heat exchangers.

6. The cooling apparatus according to claim 1, further comprising:
a reservoir tank which stores the processing liquid; and
a circulation flow path former which forms a circulation flow path for supplying the processing liquid from the reservoir tank to the heat exchanger and causing the processing liquid to flow from the heat exchanger back into the reservoir tank.

7. The cooling apparatus according to claim 6, further comprising an introduction pipe which is connected to the reservoir tank and introduces a processing liquid not temperature regulated into the reservoir tank.

8. The cooling apparatus according to claim 1, wherein the processing liquid is de-ionized water or pure water.

9. A substrate processing apparatus, comprising:
a cooling part which includes the cooling apparatus according to claim 1;
a substrate processor which processes a substrate using the processing liquid output from the cooling part; and
a supply pipe which supplies the processing liquid from the cooling part to the substrate processor.

10. A cooling method for cooling and outputting a processing liquid, the cooling method comprising:
branching a cooling medium supplied from a cooling medium supply source at a predetermined flow rate ratio into a flow path for inputting the cooling medium to a heat exchanger and a flow path bypassing the heat exchanger;
cooling the processing liquid through heat exchange with the cooling medium at the heat exchanger; and
detecting the temperature of the processing liquid output from the heat exchanger and regulating the flow rate ratio on a basis of result of the detection, thereby controlling the temperature of the processing liquid.
